(19) United States
(12) Patent Application Publication
(10) Pub. No.: US 2023/0288662 A1
(43) Pub. Date: Sep. 14, 2023

(54) METHOD FOR PRODUCING A MAIN BODY OF AN OPTICAL ELEMENT FOR SEMICONDUCTOR LITHOGRAPHY, AND MAIN BODY OF AN OPTICAL ELEMENT FOR SEMICONDUCTOR LITHOGRAPHY

(71) Applicant: Carl Zeiss SMT GmbH, Oberkochen (DE)

(72) Inventors: Franz-Josef STICKEL, Aalen-Unterrombach (DE); Andreas WOLPERT, Ellwangen (DE)

(21) Appl. No.: 18/319,617

(22) Filed: May 18, 2023

Related U.S. Application Data
(63) Continuation of application No. PCT/EP2021/080647, filed on Nov. 4, 2021.

(30) Foreign Application Priority Data
Nov. 18, 2020 (DE) 10 2020 214 466.4

(51) Int. Cl. G02B 7/18; G03F 7/20; B29D 11/00

(52) U.S. Cl. CPC G02B 7/1815; G03F 7/70891; B29D 11/00596; G03F 7/7015

(57) ABSTRACT

A method for producing a main body (33) of an optical element for semiconductor lithography includes: —producing a blank (32), —introducing at least one fluid channel (36.x) into the blank (32), then —producing the main body (33) by shaping the blank (32) onto a mold (42). Furthermore, the disclosure describes a main body (33) of an optical element that includes at least one fluid channel (36.x), the fluid channel (36.x) being embodied such that the distance between the fluid channel (36.x) and the surface (40) of the main body (33) provided for an optically active area (41) varies by less than 1 mm, preferably less than 0.1 mm and particularly preferably less than 0.02 mm.

### CROSS-REFERENCE TO RELATED APPLICATIONS

This is a Continuation of International Application PCT/EP2021/080647 which has an international filing date of Nov. 4, 2021, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2020 214 466.4 filed on Nov. 18, 2020.

### FIELD OF THE INVENTION

The invention relates to a method for producing a main body of an optical element for semiconductor lithography, and to a main body of an optical element for semiconductor lithography.

### BACKGROUND

Projection exposure apparatuses for semiconductor lithography are subject to extremely stringent requirements in respect of imaging quality in order to be able to produce the desired microscopically small structures as far as possible without defects. In a lithography process or a microlithography process, an illumination system illuminates a photolithographic mask, also referred to as reticle. The light passing through the mask or the light reflected by the mask is projected, with a projection optical unit, onto a substrate (e.g., a wafer), which is coated with a light-sensitive layer (photoresist) and fitted in the image plane of the projection optical unit, in order to transfer the structure elements of the mask to the light-sensitive coating of the substrate. The requirements in respect of the positioning of the image representation on the wafer and the intensity of the light provided by the illumination system are increased with every new generation, which results in a higher thermal load on the optical elements.

In cases of high thermal load, it may be advantageous for the optical elements embodied as mirrors, which in extreme ultraviolet (EUV) projection exposure apparatuses, that is to say in apparatuses which are operated with light having a wavelength of between 1 nm and 120 nm, in particular at 13.5 nm, to be temperature-regulated by employing water cooling. The mirrors comprise cutouts through which temperature-regulated water flows and which thereby dissipate the heat from the optically active surface, that is to say the mirror surface impinged on by the light used for imaging the structure elements. A method frequently used to produce the cutouts is drilling, which has the disadvantage that the bore holes can only be driven straight through the mirror material, with the result that the distance from the predominantly curved optically active areas varies over the radius. This in turn leads to the formation of different temperature gradients in the material and to the heat dissipation from the mirror surface varying significantly on a local level. This has disadvantageous effects on the imaging quality of the mirror.

### SUMMARY

One object of the invention is to specify an improved method which eliminates the disadvantage of the different distances between the optically active area of the optical element and the temperature control channels. Furthermore, it is an object of the invention to provide a main body for an optical element which reduces or eliminates the disadvantages of the prior art.

These objects are achieved by a method and a device having features as formulated in the independent claims. The dependent claims relate to advantageous developments and variants of the invention.

A method according to the invention for producing a main body of an optical element for semiconductor lithography comprises:
producing a blank with an optical side,
introducing at least one fluid channel into the blank, followed by
producing a main body by shaping the blank onto a mold.

The blank can be made of a material with a low coefficient of expansion such as Zerodur® by Schott AG or ULE® by Corning Incorporated, for example. These materials are distinguished by a very low thermal expansion or even no thermal expansion, with this so-called zero expansion only being reached at a certain temperature. The specified materials can preferably be used for the production of mirrors in projection exposure apparatuses. The blank can be designed as a plane-parallel plate, for example, in which at least one fluid channel embodied as a cutout is formed. The cutout can be made by drilling or another known method, such as selective etching, for example. The blank is heated before it is shaped onto the mold, and the mold can already have a geometry that corresponds to the geometry of the mirror surface that is subsequently used optically. In this context, the optical side of the blank or the main body should be understood to be that side or surface of the blank on which the optically active area of the subsequent optical element is provided.

The shaping of the blank onto the mold can be implemented by heating the blank into a temperature range below the glass transition temperature of the utilized material, for example into a temperature range of approx. 1000° C.-1400° C. for the following materials: quartz glass, Zerodur or ULE.

For example, if the blank lying on a mold is heated in a furnace, this blank, as soon as it begins to flow, will gradually adapt to the mold under the influence of gravity. This process can take several hours or even days, depending on the chosen temperature and the utilized materials. It is likewise feasible to place the mold on the blank and to shape the blank in a suitable manner in this way; the process can likewise optionally be accelerated by mass bodies that are placed on the mold or the blank and possibly adapted in terms of their shape.

In particular, the at least one fluid channel can be introduced at a constant distance from the optical side of the blank. The choice of a constant distance is advantageous in that known production methods, such as cost-effective drilling, can be used to form the fluid channel.

Furthermore, the at least one fluid channel can be introduced so that it is at a constant distance from a subsequent mirror surface of the main body after it has been shaped onto the mold. This is advantageous in that the heat conduction is constant in the case of the same heat input over the mirror surface. In this case, the movement of the material around the fluid channel can be taken into account during the shaping, or a different movement of the material surrounding the fluid channel can be provided. The differences in the movement of the material can be caused, for example, by the greater deformation in the edge region of the blank during shaping.

In addition, the cross section of the fluid channel can change as a result of the heating and the shaping. The material of the blank can be heated for the shaping until it starts to flow, whereby the material surrounding the fluid channel is also heated up to the flow temperature. In combination with the deformation of the blank during shaping, this may lead to the material surrounding the fluid channel being deformed in non-shape-preserving fashion or flowing, and the cross section of the fluid channel being changed in the process.

In particular, the at least one fluid channel can have a circular cross section after heating and shaping. A circular cross section is advantageous from a fluidics point of view. To this end, it is possible to take account of the varying deformation in the geometry chosen when the fluid channel is introduced.

As an alternative to this, the material surrounding the at least one fluid channel can be cooled during shaping. In this case, cooling can be achieved by letting a fluid flow through the fluid channel, as a result of which it is possible to keep the temperature of the material surrounding the fluid channel below the flow temperature when the blank is heated, and the geometry of the fluid channel is thus preserved during shaping. This is advantageous in that the preferred circular geometry of the at least one fluid channel can be produced cost-effectively by drilling, since this geometry is preserved after the shaping.

In particular, the temperature of the material surrounding the fluid channel can be set so that bending of the blank is possible. The temperature of the material surrounding the fluid channel can therefore advantageously be chosen such that the geometry of the fluid channel is preserved during shaping and, apart from that, the fluid channel can be shaped onto the mold together with the blank.

Furthermore, an optically active area can be formed on the optical side of the main body by finishing. The shape of the main body can already be designed with the geometry of the subsequent mirror shape, which, when the blank is shaped onto the mold, is transferred one-to-one onto the shaping surface, that is to say the surface of the blank that is in contact with the mold, and onto the opposite, for example parallel upper side of the blank. For finishing, grinding and polishing processes may therefore suffice to produce the optically active area.

Furthermore, the optically active area of the optical element can be formed to be spherical or aspherical during the finishing. In the case of a spherical surface, it is only necessary to create an optical quality of the surface without changing the geometry of the surface if the shape used has an appropriate form, as described above. In the case of an asphere, geometry changes can still be made to the surface, starting from a spherical shape, before the optical quality of the surface is created.

In particular, the at least one fluid channel can run at a constant distance from the aspherical optically active area after finishing. To this end, the adaptation of the surface to produce the asphere and hence the distance between the surface and the at least one fluid channel can already be taken into account when determining the distance between the at least one fluid channel and the surface of the blank, for example during the production of the at least one fluid channel in the blank.

In a variant of the invention, the optical side of the blank can have depressions. This may be the case when the optically active area should be designed as an asphere, in particular as a free-form asphere. Aspheres deviate from spherical form and can have depressions from an otherwise spherical surface in the optically active area. These can be so large that the resulting difference in the distance between the optically active area and the fluid channels, which were introduced at a constant distance from the subsequent optically active area in the blank, for example in the plane-parallel blank, has a non-negligible influence on the local heat conduction and hence on the local cooling capacity. The depressions introduced into the subsequent optically active area before shaping are formed as a negative of the subsequent asphere. In particular, the depressions are chosen such that fluid channels running in the region thereof are already substantially at the desired distance from the subsequent optically active area. In those regions in which depressions are provided on the subsequent optically active area to form the aspherical shape, a greater distance between the fluid channels and the optical side is deliberately set at first in this way.

Thereafter, the parameters for the heating of the blank can be set so that the depressions rest against the mold during shaping. In this case, the optical side of the blank is preferably shaped onto the mold. This initially results in a structure with different distances between the fluid channels and the surface on the optical side. In the course of finishing, depressions are then worked into the region of the greater distances between the fluid channels and the optical surface in order to design the aspherical surface. The distance between the optically active area and the fluid channels is subsequently constant over the entire surface again.

A main body according to the invention of an optical element comprises at least one fluid channel, wherein the fluid channel is formed such that the distance of the fluid channel from the optical side of the main body varies by less than 1 mm, preferably by less than 0.1 mm, and particularly preferably by less than 0.02 mm.

Furthermore, two fluid channels can be arranged at two different distances from the optical side. As a result, it is possible to individually set the local cooling capacity over the surface with a second degree of freedom.

An optical element according to the invention comprises a main body according to one of the embodiments described above, the optical element comprising an optically active area. In this case, the main body can also be stabilized, in particular, by remaining on the mold used to shape the blank.

### BRIEF DESCRIPTION OF THE DRAWINGS

Exemplary embodiments and variants of the invention are explained in more detail below with reference to the drawing, in which:

FIG. 1 shows a basic structure of an extreme ultraviolet (EUV) projection exposure apparatus in which embodiments of the invention can be implemented,

FIG. 2 shows a basic structure of a deep ultraviolet (DUV) projection exposure apparatus in which embodiments of the invention can be implemented,

FIGS. 3A-C show, in a plan view and two sections, respectively, a schematic illustration of the arrangement of the fluid channels in the blank before shaping,

FIGS. 4A and 4B show schematic illustrations for explaining two respective points in the production of a convex mirror surface,

FIG. 5A-C show schematic illustrations for explaining the production of a concave and aspheric optically active area, with reference to a blank with a depression (FIG. 5A), the blank after shaping (FIG. 5B) and the blank after subsequent removal of material (FIG. 5C), and

FIG. 6 shows a flowchart for a production method according to the invention.

### DETAILED DESCRIPTION

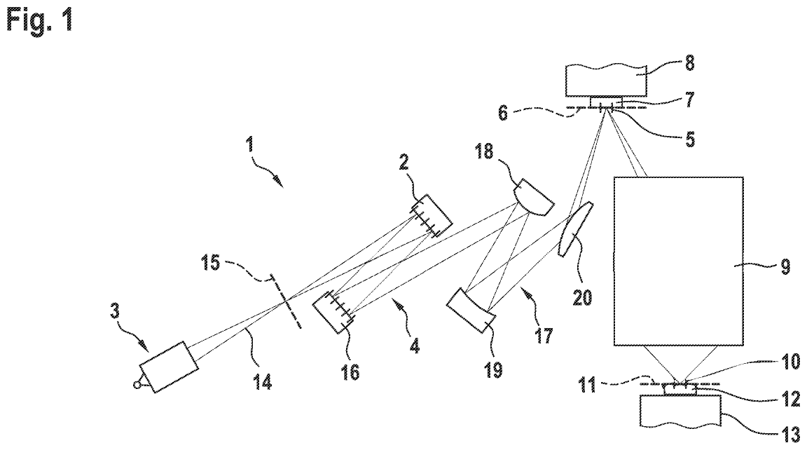

FIG. 1 shows by way of example the basic construction of a microlithographic EUV projection exposure apparatus 1 in which embodiments of the invention can be implemented. An illumination system of the projection exposure apparatus 1 has, in addition to a light source 3, an illumination optical unit 4 for the illumination of an object field 5 in an object plane 6. EUV radiation 14 in the form of optical used radiation generated by the light source 3 is aligned by via a collector, which is integrated in the light source 3, so that it passes through an intermediate focus in the region of an intermediate focal plane 15 before it is incident on a field facet mirror 2. Downstream of the field facet mirror 2, the EUV radiation 14 is reflected by a pupil facet mirror 16. With the aid of the pupil facet mirror 16 and an optical assembly 17 having mirrors 18, 19 and 20, field facets of the field facet mirror 2 are imaged into the object field 5.

A reticle 7 arranged in the object field 5 and held by a schematically illustrated reticle holder 8 is illuminated. A merely schematically illustrated projection optical unit 9 serves for imaging the object field 5 into an image field 10 in an image plane 11. A structure on the reticle 7 is imaged onto a light-sensitive layer of a wafer 12, which is arranged in the region of the image field 10 in the image plane 11 and held by a likewise partly represented wafer holder 13. The light source 3 can emit used radiation in particular in a wavelength range of between 1 nm and 120 nm.

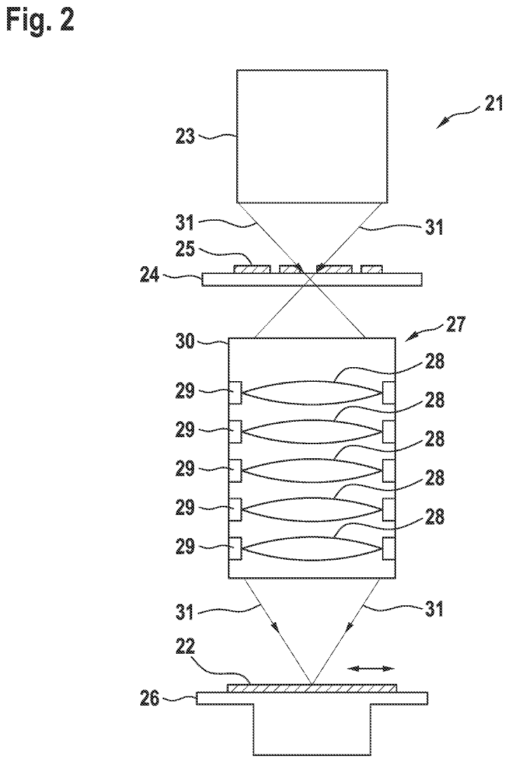

FIG. 2 illustrates an exemplary projection exposure apparatus 21 in which embodiments of the invention can be applied. The projection exposure apparatus 21 serves for imaging structures onto a substrate which is coated with photosensitive materials, and which generally consists predominantly of silicon and is referred to as a wafer 22, for the production of semiconductor components, such as computer chips.

The projection exposure apparatus 21 in this case substantially comprises an illumination device 23, a reticle holder 24 for receiving and exactly positioning a mask provided with a structure, a so-called reticle 25, by which the subsequent structures on the wafer 22 are determined, a wafer holder 26 for holding, moving and exactly positioning the wafer 22 and an imaging device, specifically a projection lens 27, with a plurality of optical elements 28, which are held with mounts 29 in a lens housing 30 of the projection lens 27.

The basic functional principle in this case provides for the structures introduced into the reticle 25 to be imaged onto the wafer 22, the imaging generally reducing the scale.

The illumination device 23 provides a projection beam 31 in the form of electromagnetic radiation, which is required for the imaging of the reticle 25 onto the wafer 22, the wavelength range of this radiation lying between 100 nm and 300 nm, in particular. The source used for this radiation may be a laser, a plasma source or the like. Optical elements in the illumination device 23 are used to shape the radiation such that, when incident on the reticle 25, the projection beam 31 has the desired properties with regard to diameter, polarization, form of the wavefront and the like.

An image of the reticle 25 is produced by the projection beam 31 and transferred from the projection lens 27 onto the wafer 22 in an appropriately reduced form, as already explained above. In this case, the reticle 25 and the wafer 22 can be moved synchronously, so that regions of the reticle 25 are imaged onto corresponding regions of the wafer 22 virtually continuously during what is called a scanning operation. The projection lens 27 has a multiplicity of individual refractive, diffractive and/or reflective optical elements 28, such as for example lens elements, mirrors, prisms, terminating plates and the like, wherein these optical elements 28 can be actuated for example with one or more actuator arrangements (not shown here).

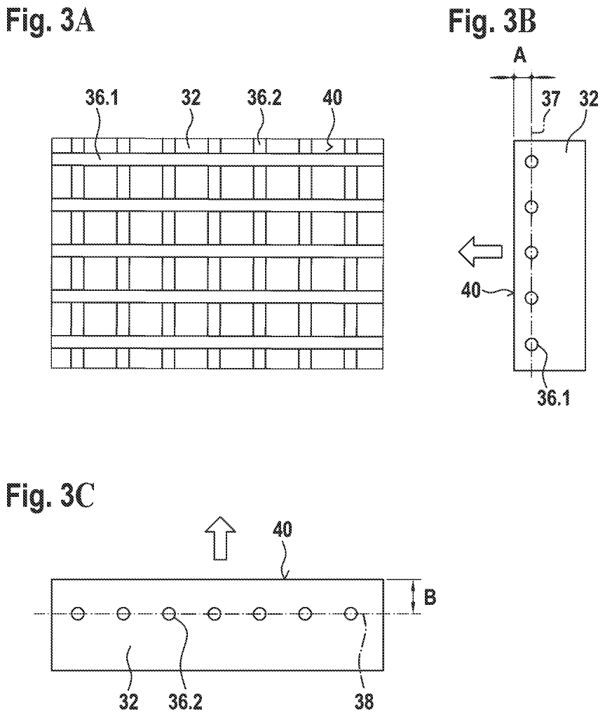

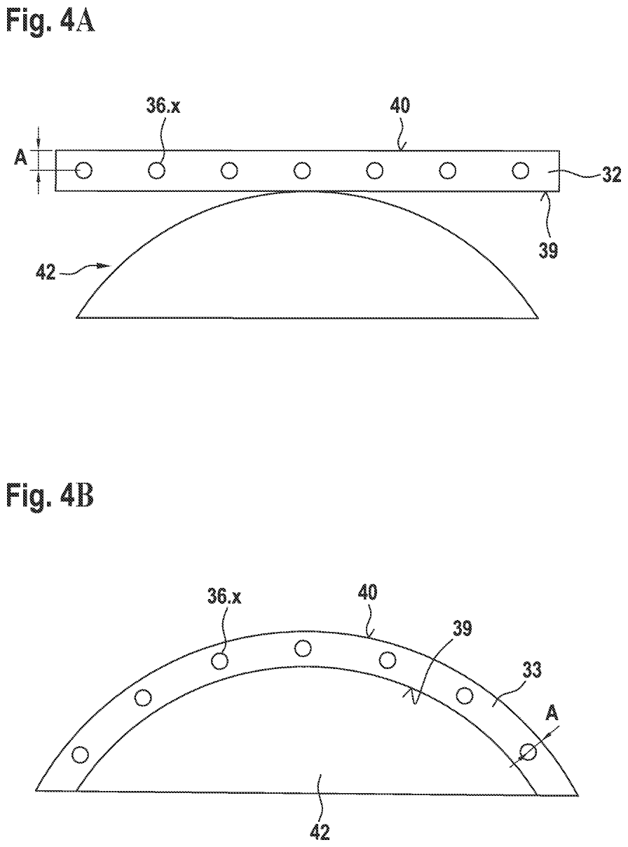

FIG. 3A shows a plan view of a schematic illustration, in which a blank 32 of a subsequent main body of an optical element designed as a mirror, for example, is shown. In this case, the blank 32 is a plane-parallel plate and, according to the method described in FIGS. 4A and 4B, becomes the main body of the subsequent mirror. The blank 32 is traversed by fluid channels 36.x which are produced by drilling, for example, and are arranged in two planes 37, 38 (cf. FIGS. 3B and 3C) in the example shown. In this case, the fluid channels 36.1 of a first plane 37 are formed at right angles to the fluid channels 36.2 of the second plane 38 and the planes are at different distances from the optical side 40 of the blank 32. In this case, the optical side 40 of the blank 32 is that surface which is provided for the subsequent optically active area, that is to say that surface of the subsequent optical element through which its optical effect on incident electromagnetic radiation is achieved.

FIG. 3B shows a side view of the blank 32, in which the fluid channels 36.1 of the first plane 37 are arranged at a distance A from the optical side 40 of the blank 32.

FIG. 3C shows a further side view of the blank 32, in which the fluid channels 36.2 of the second plane 38 are arranged at a distance B from the optical side 40 of the blank 32. The distance A of the first plane shown in FIG. 3B is smaller than the distance B in this case. The arrangement of the fluid channels 36.x in the blank 32 is arbitrary and, in addition to the arrangement shown, can also be designed in a meandering shape, for example. A meandering fluid channel 36.x can be produced by selective etching, for example. Alternatively, the fluid channels 36.x can also be arranged in three or more planes and parallel to one another.

FIG. 4A shows the initial situation during the production of a mirror, for example, illustrating a mold 42 and a blank 32 which has not yet been shaped. The mold 42 already exhibits the geometry of the subsequent mirror surface. The blank 32 with the fluid channels 36.x arranged at a distance A from the optical side 40 is placed with the shaping surface 39, which is opposite the optical side 40, onto the mold 42 and then heated together with the latter. Alternatively, the blank 32 and the mold 42 can also be heated to a temperature that allows the blank 32 to be shaped onto the mold 42, before the blank 32 is placed on the mold 42. The temperature is chosen so that, as a result of the gravitational force, the material of the blank 32 rests against the shaping surface 39, that is to say changes the shape without changing the thickness, for example.

FIG. 4B shows the mirror main body 33 created from the blank 32 after it has been shaped onto the mold 42. The distance A of the fluid channels 36.x from the optical surface 40 is identical or almost identical to the distance A in the blank 32, as a result of which the fluid channels 36.x are arranged at a constant distance A from the optical side 40. The subsequent removal for the creation of an optically active area on the optical side 40 and, optionally, the application of a coating are negligible in relation to the effect on the heat conduction to the cooling fluid flowing through the fluid channels 36.x.

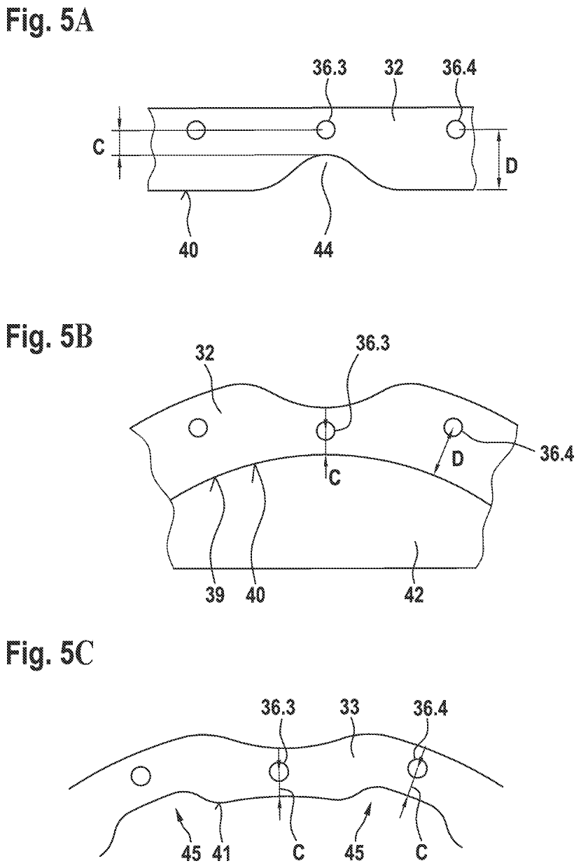

FIGS. 5A to 5C show the production process of a concave aspherical main body 33 (cf. FIG. 5C) for a subsequent mirror, which comprises two bulges 45 as parts of its aspherization in the example shown. A special design of the blank 32 is advantageous in order to be able to ensure that the fluid channels 36.3 and 36.4 are at the same distance from the optically active area 41 (cf. FIG. 5C) for such geometries as well.

FIG. 5A shows a blank 32 with fluid channels 36.3, 36.4 and a cutout 44 formed in the optical side 40. In this case, the depression 44 is only formed in the region of the optical side 40 from which there is no further removal during the following process for producing the subsequent optically active area 41. It is quite evident from FIG. 5A that the distance C of the fluid channel 36.3 from the optical side 40 is less than the distance D of the fluid channel 36.4.

FIG. 5B shows the blank 32 after shaping onto the mold 42, with the shaping surface 39 shown there now corresponding to the optical surface 40, in contrast with the production method described in FIGS. 4A and 4B. During shaping, the material in the region of the depression 44 sinks onto the mold 42, with the fluid channel 36.3 arranged in the region of the depression 44 likewise being displaced in the direction of the mold 42. The distance C of the fluid channel 36.3 in the region of the depression 44 and the distance D of the fluid channels 36.4 in the region without depressions 44 in relation to the optical surface 40 has not changed significantly after the shaping.

FIG. 5C shows the main body 33 created from the blank 32 after the formation of aspheres 45 in the optically active area 41 then created, the aspheres 45 being formed by removing material from those regions of the main body 33 in which no depressions 44 are formed in the blank 32 shown in FIG. 5A. As a result, the two fluid channels 36.3, 36.4 are at the same distance C from the optically active area 41 then created, whereby uniform heat conduction to the fluid channels 36.3, 36.4 is ensured.

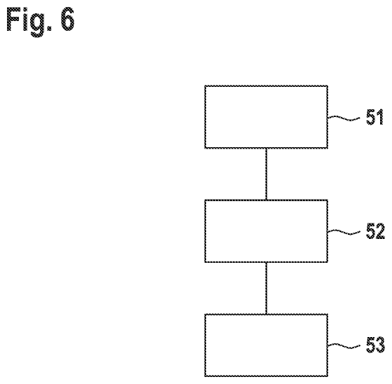

FIG. 6 shows a flowchart of a feasible method for producing a main body 33 of an optical element for semiconductor lithography.

A blank is produced in a first method step 51. At least one fluid channel 36.x is introduced into the blank 32 in a second method step 52. Then, in a third method step 53, the main body 33 is produced by shaping the blank 32 onto a mold 42.

### LIST OF REFERENCE SIGNS

1 Projection exposure apparatus
2 Field facet mirror
3 Light source
4 Illumination optical unit
5 Object field
6 Object plane
7 Reticle
8 Reticle holder
9 Projection optical unit
10 Image field
11 Image plane
12 Wafer
13 Wafer holder
14 EUV radiation
15 Intermediate field focal plane
16 Pupil facet mirror
17 Assembly
18 Mirrors
19 Mirrors
20 Mirrors
21 Projection exposure apparatus
22 Wafer
23 Illumination optical unit
24 Reticle holder
25 Reticle
26 Wafer holder
27 Projection lens
28 Optical element
29 Mounts
30 Lens housing
31 Projection beam
32 Blank
33 Main body
36.1-36.4 Fluid channel
37 Fluid channel plane 1
38 Fluid channel plane 2
39 Shaping surface
40 Mirror surface
41 Optically effective surface
42 Mold
44 Depression
45 Asphere
51 Method step 1
52 Method step 2
53 Method step 3
A, B, C, D Distance between fluid channel and surface

What is claimed is:

1. A method for producing a main body of an optical element for semiconductor lithography, comprising:
producing a blank with an optical side,
introducing at least one fluid channel into the blank, and
thereafter producing the main body by shaping the blank onto a mold.

2. The method as claimed in claim 1,
wherein said shaping of the blank comprises heating the blank.

3. The method as claimed in claim 1,
wherein said introducing comprises introducing the at least one fluid channel at a constant distance from the optical side of the blank.

4. The method as claimed in claim 1,
wherein said introducing comprises introducing the fluid channel such that the fluid channel defines a constant distance between the fluid channel and an optical surface of the main body after the main body has been shaped onto the mold.

5. The method as claimed in claim 1,
wherein a cross section of the at least one fluid channel changes in response to the shaping.

6. The method as claimed in claim 1,
wherein the at least one fluid channel has a circular cross section after said shaping.

7. The method as claimed in claim 1,
wherein said shaping of the blank comprises cooling a material surrounding the at least one fluid channel.

8. The method as claimed in claim 7,
wherein said cooling comprises setting a temperature of the material surrounding the at least one fluid channel to permit the material to bend.

9. The method as claimed in claim 1,
further comprising finishing the main body by forming an optically active area on the optical side of the main body.

10. The method as claimed in claim 9,
wherein the optically active area of the optical element is formed to be spherical or aspherical during said finishing.

11. The method as claimed in claim 10,
wherein the at least one fluid channel runs at a constant distance from the aspherical optically active area after said finishing.

12. The method as claimed in claim 1,
wherein the optical side of the blank comprises depressions.

13. The method as claimed in claim 12,
wherein parameters for said shaping of the blank are set so that the depressions rest against the mold during said shaping.

14. An optical element comprising:
a main body having an optical side, and
at least one fluid channel in the main body,
wherein a distance between the at least one fluid channel and the optical side of the main body varies by less than 1 mm.

15. The optical element as claimed in claim 1,
wherein the distance between the at least one fluid channel and the optical side of the main body varies by less than 0.02 mm.

16. The optical element as claimed in claim 14,
wherein two fluid channels are arranged at two different distances from the optical side of the main body.
